(19) United States
(12) Patent Application Publication
(10) Pub. No.: US 2006/0110866 A1
(43) Pub. Date: May 25, 2006

(54) Method for fabricating thin film transistors

(75) Inventors: Feng-Yuan Gan, Hsinchu City (TW); Han-Tu Lin, Wuci Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/142,928

(22) Filed: Jun. 2, 2005

(30) Foreign Application Priority Data
Nov. 22, 2004 (TW) 93135856

(51) Int. Cl. H01L 21/00

(52) U.S. Cl. 438/151

(57) ABSTRACT

Thin film transistor fabrication methods. A gate electrode is formed on a substrate. The surface of metal gate is subjected to a hydrogen plasma treatment to remove a native oxide formed thereon. A nitride layer as a buffer layer is formed to cover the metal gate. A gate insulating layer is formed on the buffer layer. A semiconductor layer is formed on the gate insulating layer. A source/drain layer is formed on the semiconductor layer. The buffer layer prevents the metal gate from damage in subsequent plasma enhanced chemical vapor deposition processes.

### BACKGROUND

The invention relates to method for fabricating thin film transistors and, more particularly, to thin film transistors with novel gate electrode structure.

Bottom gate type thin film transistors have been widely used in thin film transistor-liquid crystal display (TFT-LCD). FIG. 1a is a cross-section illustrating a conventional bottom gate type thin film transistor 100. The thin film transistor 100 comprises a glass substrate 110, a metal gate electrode 120, a gate insulator 130, a channel layer 140, an ohmic contact lay 150, and source/drain electrodes 160 and 170.

With the increasing dimensions of TFT-LCDs, it has become important for gate electrodes thereof to have metal gate lines with reduced resistivity. In order to fabricate a thin film transistor with low power consumption and high response time, low resistivity conductive materials such as copper have gradually replaced conventional conductive materials such as aluminum.

Use of copper (Cu), however, may be problematic due to the very active reaction of copper. Copper as gate electrode 120 material in TFT devices often reacts with the plasma in plasma enhanced chemical vapor deposition (PECVD) for the subsequent preparation of gate insulator 130 of silicon nitride or silicon oxide. Copper is active and likely to react with the gases used in PECVD such as O₂ or NH₃. The reaction products such as copper oxide or copper nitride render the top surface 180 of the copper gate electrode rough and uneven. Thus, roughness and resistivity of the copper gate electrode 120 is increased. FIG. 1b is a close-up cross-section view of location A shown in FIG. 1a. The carrier mobility of the channel layer 140 would be reduced by increasing roughness of the gate electrode surface, resulting in inferior TFT performance.

Thus, simple and efficient TFT manufacturing method preventing a copper gate electrodes from being affected by subsequent gate insulator preparation is desirable.

### SUMMARY

Method for fabricating thin film transistors is provided. In a exemplary embodiment of a method for fabricating a thin film transistor, a substrate is first provided. A gate electrode is formed on the substrate and subjected to a plasma treatment to remove a nativr oxide formed thereon. A buffer layer is formed to cover the gate electrode. A gate insulating layer is formed on the buffer layer. A channel layer is formed on the gate insulating layer. Source and drain electrodes are formed on part of the channel layer.

Some embodiments of a method for fabricating thin film transistors may also comprise providing a substrate. A gate electrode is formed on the substrate and subjected to a hydrogen plasma treatment to remove a native oxide formed thereon. A nitride buffer layer is formed to cover the gate electrode. A gate insulating layer is formed on the nitride buffer layer. A channel layer is formed on the gate insulating layer. Source and drain electrodes are formed on part of the channel layer. Particularly, the gate electrode can be a copper gate electrode, and the buffer layer is a copper nitride layer.

A detailed description is given in the following with reference to the accompanying drawings.

### DESCRIPTION OF THE DRAWINGS

The methods for fabricating thin film transistors can be more fully understood by reading the subsequent detailed description in conjunction with the examples and references made to the accompanying drawing, wherein:

FIG. 1a is a cross-section illustrating a conventional bottom gate type thin film transistor.

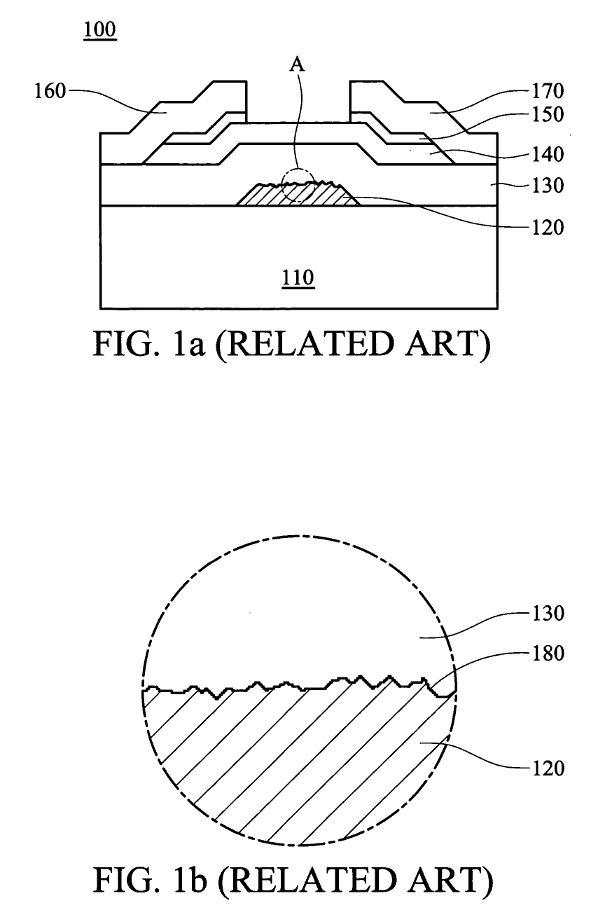

FIG. 1b is a close-up cross-section view of location A shown in FIG. 1a.

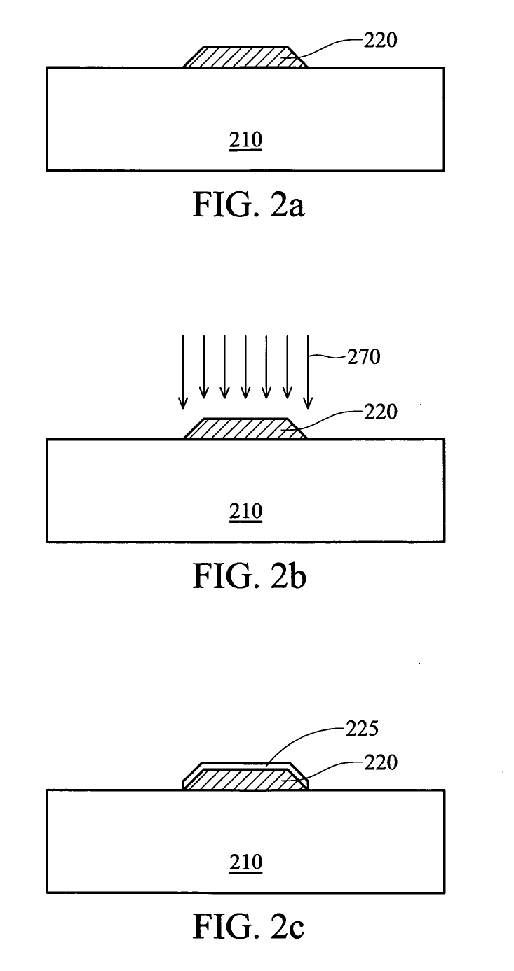

FIGS. 2a-2e are cross-sections of an embodiment of a method for forming a thin film transistor.

### DETAILED DESCRIPTION

Methods for fabricating thin film transistors will now be described in greater detail.

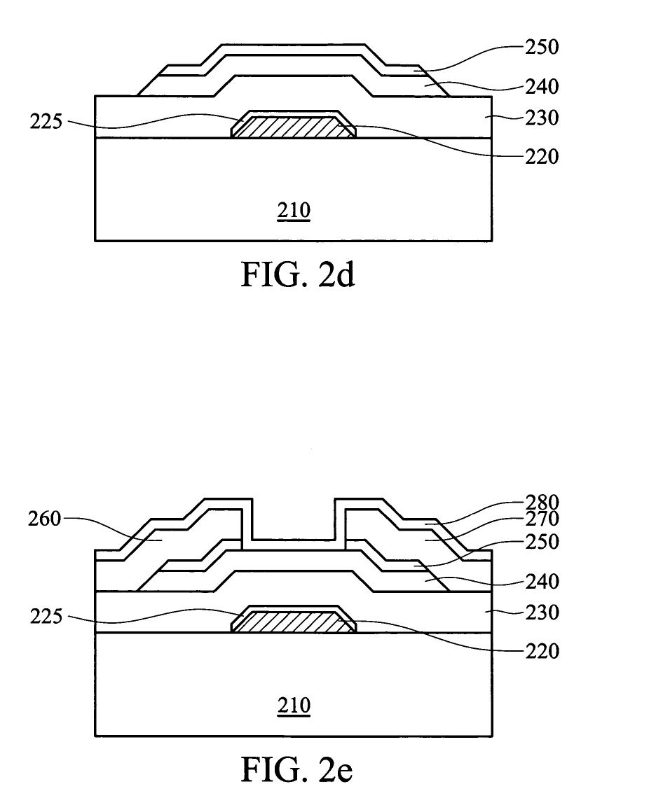

FIGS. 2a to 2e are cross-sections of a process for forming a thin film transistor.

In FIG. 2a, a conductive layer (not shown) is formed on a substrate 210, and can be Al, Mo, Cr, W, Ta, Cu, Ag, Ag—Pd—Cu, polysilicon, or combinations thereof. Preferably, the conductive layer comprises Cu or Ag. Most preferably, the conductive layer is Cu. An embodiment of the method of forming the conductive layer comprises, but is not limited to, vapor deposition, or sputtering. The substrate 210 is an insulating substrate, such as glass substrate or quartz substrate. The conductive layer is patterned to form a gate electrode 220 by lithography. As shown in FIG. 2a, the gate electrode 220, with taper sidewalls formed by etching, has conformal step coverage. An adhesion layer can be further formed between the substrate 210 and the gate electrode 220, to increase adhesion therebetween.

Referring to FIG. 2b, a plasma treatment 270, is performed to remove a native oxide formed on the surface of the gate electrode 220, such as copper oxide or silver oxide (depending on gate materials), of a few seconds to a few minutes, preferably 10 to 30 sec. Note that gases with reduction properties, such as hydrogen gas, are used in the plasma treatment 270 to reduce metal oxides to element metals.

Referring to FIG. 2c, a buffer layer 225 is formed to completely cover the gate electrode 220. The buffer layer 225 comprises a metal nitride compound, such as copper nitride or silver nitride (depending on gate materials), which is formed by nitrogenization of the gate metal. The thickness of the buffer layer can be 30-300 Å, more preferably 50-200 Å, most preferably 100-150 Å. An embodiment of a method of forming the buffer layer 225 can comprise performing a nitrogen plasma treatment on the gate electrode 220. The buffer layer 225 can alternatively be formed by performing an annealing treatment on the gate electrode 220 with NH₃ or N₂ gas present at 200˜400° C. for 1-30 min. Particularly, the process of forming the buffer layer 225 is an in-siut step, and the grown nitride is uniformly and conformally formed on the gate electrode surface, without damaging to the electrode gate 220 or adversely affecting the TFT.

Referring to FIG. 2d, a gate insulating layer 230 is formed over the substrate to cover the buffer layer 225. The gate insulating layer 230 comprises silicon oxide, silicon nitride, silicon oxynitride, tantalum oxide, or aluminum oxide, and formed by the gate insulating layer 230 can be plasma enhanced chemical vapor deposition (PECVD). A semiconductor layer (not shown) is subsequently formed on the gate insulating layer 230. The semiconductor layer comprises polysilicon or amorphous-silicon, and can be formed by chemical vapor deposition. Next, the semiconductor layer is patterned to form a channel layer 240 by lithography, and an ohmic contact layer 250 comprising impurity-added silicon is formed on the channel layer 240. The ohmic contact layer 250 can be formed by implanting n-type ions, such as P or As ions, into a silicon layer.

Referring to FIG. 2e, a metal layer (not shown) is formed on the ohmic contact layer 250 and gate insulating layer 230. The metal layer comprises Al, Mo, Cr, W, Ta, Ti, Ni, or combinations thereof, and can be formed by vapor deposition or sputtering. The metal layer is subsequently patterned to form a source electrode 260 and a drain electrode 270 by lithography. Next, the ohmic contact layer 250 is etched with the source and drain electrodes 260 and 270 acting as mask to expose a part of the top surface of the channel layer 140.

Finally, a protective layer 280 is formed over the substrate 210 to protect the thin film transistor from being damaged, thus completing fabrication of the thin film transistor 200. In some embodiments of methods for fabricating thin film transistors, the gate electrode 220 and gate lines with the nitride buffer layer 230 formed thereon can also be formed simultaneously.

Accordingly, since the gate electrode is subjected to hydrogen plasma treatment to remove oxides formed thereon, resistivity and roughness of the gate electrode are reduced. Furthermore, before forming a gate insulating layer on the gate electrode, the buffer layer is formed in-situ from the gate electrode to protect the gate electrode from reacting with gases used in forming the gate insulating layer. Thus, the described methods for fabricating thin film transistors can meet current market demands for increasing stability and efficiency.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. A method of fabricating a thin film transistor, comprising:
providing a substrate;
forming a gate electrode on the substrate, wherein a native oxide is presented on the gate electrode;
performing a plasma treatment to remove the native oxide formed on the surface of the gate electrode;
forming a buffer layer covering the gate electrode;
forming a gate insulating layer on the buffer layer;
forming a channel layer on the gate insulating layer; and
forming a source electrode and a drain electrode on part of the channel layer.

2. The method as claimed in claim 1, wherein performing the plasma treatment comprises providing hydrogen gas.

3. The method as claimed in claim 1, wherein forming the buffer layer comprises performing a nitrogen plasma treatment on the gate electrode.

4. The method as claimed in claim 1, wherein forming the buffer layer comprises performing an annealing treatment with NH₃ or N₂ gas present at 200-400° C. to the gate electrode.

5. The method as claimed in claim 1, wherein the gate electrode comprises Al, Mo, Cr, W, Ta, Cu, Ag, Pd, or combinations thereof.

6. The method as claimed in claim 1, wherein the gate electrode comprises Cu, Ag, or combination thereof.

7. The method as claimed in claim 1, wherein the buffer layer comprises copper nitride.

8. The method as claimed in claim 1, wherein the gate insulating layer comprises silicon oxide, silicon nitride, silicon oxynitride, tantalum oxide, or aluminum oxide.

9. The method as claimed in claim 1, wherein forming the channel layer comprises performing a chemical vapor deposition.

10. The method as claimed in claim 1, wherein the channel layer comprises a semiconductor layer.

11. The method as claimed in claim 1, wherein the source and drain electrodes comprise metal.

12. The method as claimed in claim 1, wherein the source and drain electrodes comprise Al, Mo, Cr, W, Ta, Ti, Ni, or combinations thereof.

13. The method as claimed in claim 1, further comprising, before forming the gate electrode, forming an adhesion layer on the substrate.

14. A method of fabricating a thin film transistor, comprising:
providing a substrate;
forming a gate electrode on the substrate, wherein a native oxide is presented on the gate electrode;
performing a hydrogen plasma treatment to remove the native oxide formed on the surface of the gate electrode;
forming a nitride buffer layer covering the gate electrode;
forming a gate insulating layer on the nitride buffer layer;
forming a channel layer on the gate insulating layer; and
forming source and drain electrodes on part of the channel layer.

15. The method as claimed in claim 14, wherein the gate insulating layer comprises silicon oxide, silicon nitride, silicon oxynitride, tantalum oxide, or aluminum oxide.

16. The method as claimed in claim 14, wherein forming the channel layer comprises performing a chemical vapor deposition.

17. The method as claimed in claim 14, wherein the channel layer comprises a semiconductor layer.

18. The method as claimed in claim 14, wherein the source and drain electrodes comprise Al, Mo, Cr, W, Ta, Ti, Ni, or combinations thereof.

19. The method as claimed in claim 14, further comprising, before forming the gate electrode, forming an adhesion layer on the substrate.

20. The method as claimed in claim 14, wherein the gate electrode comprises copper.

21. The method as claimed in claim 14, wherein the nitride buffer layer comprises copper nitride.

22. The method as claimed in claim 14, wherein forming the nitride buffer layer comprises performing a nitrogen plasma treatment to the gate electrode.

23. The method as claimed in claim 14, wherein forming the nitride buffer layer comprises performing an annealing treatment with NH₃ or N₂ gas present at 200-400° C. on the gate electrode.
